(19) United States
(12) Patent Application Publication
(10) Pub. No.: US 2014/0251540 A1
(43) Pub. Date: Sep. 11, 2014

(54) SUBSTRATE SUPPORTER AND SUBSTRATE PROCESSING APPARATUS INCLUDING THE SAME

(71) Applicant: CHARM ENGINEERING CO., LTD., Yongin-Si (KR)

(72) Inventors: Young-Soo SEO, Osan-Si (KR); Young-Ki HAN, Seoul (KR); Jun-Hyeok LEE, Osan-Si (KR); Kyu-Sang LEE, Goyang-Si (KR)

(73) Assignee: CHARM ENGINEERING CO., LTD., Yongin-Si (KR)

(21) Appl. No.: 14/204,541

(22) Filed: Mar. 11, 2014

(30) Foreign Application Priority Data
Mar. 11, 2013 (KR) 10-2013-0025602

(51) Int. Cl. H01J 37/32

(52) U.S. Cl. CPC H01J 37/32715; H01J 37/32724; H01J 37/3244
USPC 156/345.29; 118/500; 118/723 R; 118/723 IR; 156/345.51; 156/345.52

(57) ABSTRACT

Provided is a substrate processing apparatus including a chamber provided with a reaction space and formed with an exhaustion opening in a center of a bottom, a substrate supporter provided in the chamber and supporting a substrate, a gas injection assembly provided to be opposite to the substrate supporter, injecting a processing gas, and generating plasma thereof, and an exhauster connected to the exhaustion opening and provided below the chamber to exhaust an inside of the chamber, in which the substrate supporter includes a substrate support supporting the substrate and a plurality of supporting posts supporting an outside of the substrate support disposing the exhausting opening therebetween.

### CROSS-REFERENCE TO RELATED APPLICATION

This application claims priority to Korean Patent Application No. 10-2013-0025602 filed on Mar. 11, 2013 and all the benefits accruing therefrom under 35 U.S.C. §119, the contents of which are incorporated by reference in their entirety.

### BACKGROUND

The present disclosure relates to a substrate supporter and a substrate processing apparatus including the substrate supporter, and more particularly, to a substrate supporter allowing an internal gas flow to be uniform and a substrate processing apparatus including the substrate supporter.

Generally, in order to manufacture semiconductor devices, displays, light emitting diodes (LED), or thin film transistor solar batteries, a semiconductor process is used.

That is, a certain lamination structure is formed by a plurality of times repetitively performing a thin film vapor deposition process of vapor-depositing a thin film of a certain material on a substrate, a photo process of exposing a selected area of the thin films by using a photosensitive material, and an etching process of patterning by removing the thin film in the selected area.

As a thin film vapor deposition process, a chemical vapor phase deposition (CVD) method may be used. In the CVD method, a processing gas supplied into a chamber causes a chemical reaction on a top surface of a substrate, thereby growing a thin film. Also, in order to improve film properties of a thin film, plasma enhanced CVD (PECVD) method may be used. General PECVD apparatuses include a chamber provided with a certain space therein, a shower head provided on a top of an inside of the chamber, a substrate support provided on a bottom of the inside of the chamber and supporting the substrate, and a plasma generation source such as an electrode or an antenna provided inside or outside the chamber. Also, in a central part of a bottom of the substrate support, one supporting post supporting the substrate support is formed penetrating through a central part of the bottom of the chamber. Korean Patent Registration No. 10-1234706 discloses an example of a substrate processing apparatus including the substrate support.

A stable uniform plasma generation source and a uniform gas flow inside a chamber are most important to deposit a thin film using the PECVD apparatus. However, due to an imbalance in a pumping path for exhausting an inside of the chamber, the gas flow inside the chamber becomes ununiform, thereby deteriorating deposition properties of a thin film and generating particles. For example, since a supporting post is provided in a central part of a bottom of the chamber, it is necessary to form an exhaust opening on an outside of the bottom of the chamber. According thereto, an area formed with the exhaust opening and other areas have different exhaust times from one another. Accordingly, gas stay times on the substrate differ, thereby deteriorating deposition uniformity of a thin film. Particularly, in case of a process of a low pressure of approximately 20 mTorr or less, since a small amount of a raw material flows into a chamber, there is a limitation in improving deposition uniformity using a gas.

To overcome the limitation, several methods have been used. As most representative methods, there are a method of mounting a manifold and a method of forming at least one exhaust opening on a side of a chamber. However, since the supporting post is provided in the central part of the bottom of the chamber, an exhaust device is installed on the side of the chamber. Also, when a turbo pump is mounted to perform the low pressure process, since the supporting post is provided in the central part of the bottom of the chamber, the turbo pump is provided on the side of the chamber. When the exhaust device is provided on the side of the chamber as described above, there is a limitation in allowing pressure inside the chamber to be uniform. Also, when several components are inserted into the chamber, uniformity of plasma may receive an effect.

### SUMMARY

The present disclosure provides a substrate supporter capable of allowing a gas flow inside a chamber to be uniform and a substrate processing apparatus including the substrate supporter.

The present disclosure also provides a substrate supporter, in which an exhaust opening and an exhaust device are provided in a central part of a bottom of a chamber and a supporting post is formed on an outside of a substrate support not to interfere with the exhaust opening and the exhaust device, thereby allowing a gas flow inside the chamber to be uniform, and a substrate processing apparatus including the substrate supporter.

In accordance with an exemplary embodiment, a substrate supporter includes a substrate support supporting a substrate and a plurality of supporting posts supporting an edge of the substrate support below the substrate support.

The substrate supporter may further include a plurality of projecting portions projecting outwards from the edge of the substrate support, and the plurality of supporting posts may support bottoms of the projecting portions, respectively.

The substrate support may include a first area in contact with a rear of the substrate and heating the substrate while maintaining a first temperature and a second area provided outside the first area and maintaining a second temperature higher or lower than the first temperature.

The second area may be provided higher or lower than the first area.

In accordance with another exemplary embodiment, a substrate processing apparatus includes a chamber provided with a reaction space and formed with an exhaustion opening in a center of a bottom, a substrate supporter provided in the chamber and supporting a substrate, a gas injection assembly provided to be opposite to the substrate supporter, injecting a processing gas, and generating plasma thereof, and an exhauster connected to the exhaustion opening and provided below the chamber to exhaust an inside of the chamber, in which the substrate supporter includes a substrate support supporting the substrate and a plurality of supporting posts supporting an outside of the substrate support disposing the exhausting opening therebetween.

The substrate processing apparatus may further include a plurality of projecting portions projecting outwards from an edge of the substrate support, and the plurality of supporting posts may support the projecting portions, respectively.

The substrate support may include a first area in contact with a rear of the substrate and heating the substrate while maintaining a first temperature and a second area provided outside the first area and maintaining a second temperature higher or lower than the first temperature.

The gas injection assembly may include a gas injection unit injecting the processing gas, a power unit for applying high frequency power to the gas injection unit, and a ground plate provided to be separate from the gas injection unit with a certain interval and formed with a plurality of penetration holes.

The substrate processing apparatus may further include a filter provided between the gas injection unit and the substrate supporter and formed with a plurality of holes to shut out a part of plasma of the processing gas.

The gas injection assembly may include a gas injection unit injecting the processing gas, an electrode separate from the gas injection unit, and a power unit for applying high frequency power to the electrode.

The substrate processing apparatus may further include a filter provided between the gas injection unit and the substrate supporter and formed with a plurality of holes to shut out a part of plasma of the processing gas.

The gas injection assembly may include a gas injection unit injecting the processing gas, an antenna provided on one of a top and a side of an outside of the chamber, and a power unit applying high frequency power to the antenna.

The gas injection assembly may include an upper body, a first body disposed below the upper body to be separate therefrom, a second body disposed below the first body and provided with a plurality of first injection holes and a plurality of second injection holes, a connecting pipe including an inner space and installed to penetrate the first body and the second body top and bottom, a power supplying unit applying power to at least one of the upper body, the first body, and the second body to form a plasma area between the upper body and the first body and a plasma area between the first body and the second body.

The substrate processing apparatus may further include a first gas supply pipe supplying the processing gas to the upper body and a second gas supply pipe supplying the processing gas to an area between the first body and the second body.

The first body may be connected to the power supplying unit, and the upper body and the second body may be grounded.

The upper body may be connected to a first power supplying unit, a second body may be connected to a second power supplying unit, and the first body may be grounded.

The upper body may be formed with a plurality of holes connected top and bottom.

The first injection holes and the second injection holes may be alternately disposed to be separate from one another.

The connecting pipe may be manufactured using an insulating material.

The connecting pipe may penetrates the first body and may be inserted into and installed in the second injection holes of the second body.

Among areas of the connecting pipe, an area connected to the first body may have a diameter greater than a diameter of an area connected to the second body.

### BRIEF DESCRIPTION OF THE DRAWINGS

Exemplary embodiments can be understood in more detail from the following description taken in conjunction with the accompanying drawings, in which:

FIG. 1 is a perspective view of a substrate supporter according to an exemplary embodiment;

FIG. 2 is a top view of the substrate supporter of FIG. 1;

FIGS. 3A to 3D are partial cross-sectional views illustrating examples of the substrate supporter of FIG. 1;

FIGS. 4 and 5 are a longitudinal cross-sectional view and a lateral cross-sectional view of a substrate processing apparatus according to an exemplary embodiment;

FIGS. 6 and 7 are cross-sectional views of substrate processing apparatuses according to other exemplary embodiments, respectively; and

FIGS. 8 to 10 are cross-sectional views of substrate processing apparatuses according to still other exemplary embodiments, respectively.

### DETAILED DESCRIPTION OF EMBODIMENTS

Hereinafter, embodiments of the present invention will be described. However, the present invention is not limited to the embodiments disclosed below but may be embodied as various different shapes. Merely, the embodiments below are provided to fully disclose the present invention and to allow a person of ordinary skill in the art to consummately know the scope of the present invention.

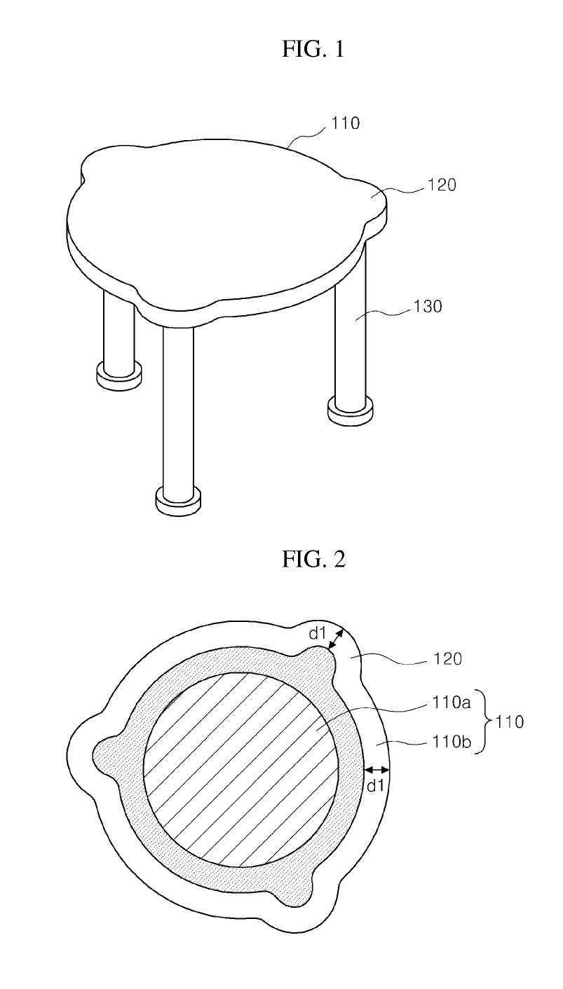

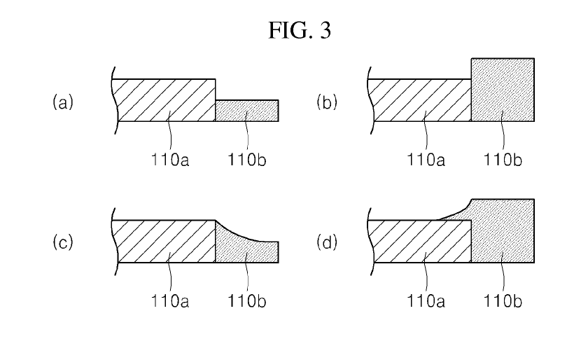

FIG. 1 is a perspective view of a substrate supporter according to an embodiment of the present invention, FIG. 2 is a top view of the substrate supporter, and FIG. 3 is a partial cross-sectional view of the substrate supporter.

Referring to FIGS. 1 to 3, the substrate supporter includes a substrate support 110 on which a substrate is seated, a plurality of projecting portions 120 provided on an outside of the substrate support 110, and a plurality of supporting posts 130 provided on bottoms of the plurality of projecting portions 120 and supporting the respective projecting portions 120. That is, in the substrate supporter, the plurality of supporting posts 130 support the substrate support 110 on an edge of a bottom of the substrate support 110.

The substrate support 110 supports the substrate. The substrate support 110, for example, is provided with an electrostatic chuck to allow the substrate to be adsorbed and kept by an electrostatic force. However, the substrate support 110 may keep the substrate using vacuum adsorption or a mechanical force in addition to the electrostatic force. The substrate support 110 may be provided according to a shape of the substrate, for example, as a circular shape. However, when the substrate has a rectangular shape, the substrate support 110 may be formed to have a rectangular shape. Also, the substrate support 110 may be mounted with a heater (not shown) therein. The heater generates heat at a certain temperature and applies the heat to the substrate to allow a thin film deposition process to be easily performed on the substrate. The heater may be a halogen lamp and may be installed in a circumferential direction of the substrate support 110 around the substrate support 110. In this case, generated energy is radiant energy heating the substrate support 110 to increase a temperature of the substrate. On the other hand, inside the substrate support 110, in addition to the heater, a cooling tube (not shown) may be further provided. The cooling tube allows refrigerants to circulate through an inside of the substrate support 110, thereby allowing cold to be transferred to the substrate through the substrate support 110 to control the temperature of the substrate to be desirable. As described above, the substrate may be heated by the heater provided inside the substrate support 110 and may be heated to a temperature of from about 50 to 800 by controlling the number of the heaters. The substrate support 110 may be divided into a plurality of areas according to a temperature. That is, the substrate support 110 may include a first area 110a for allowing the substrate to be seated and increasing the temperature of the substrate to a processing temperature and a second area 110b provided outside the first area 110a and compensating a temperature of an edge of the substrate. The first area 110a may be greater than or identical to the substrate to allow the substrate to be seated thereon and to be heated. However, the heater, for example, is disposed in a circumferential direction of the substrate support 110 from a center of the first area 110a in such a way that the edge of the substrate may be at a lower temperature than other areas. According to a shape of disposing the heater, the temperature of the edge of substrate may be higher than those of the other areas. Accordingly, to compensate the temperature of the edge based on the center of the substrate, the second area 110b is provided outside the first area 110a. The second area 110b may be provided while being in contact with an outside of the first area 110a and being separate from the edge of the substrate support 110 with a certain distance d. That is, the second area 110b may be provided between the first area 110a and the edge of the substrate support 110 with a certain width. The second area 110b may be heated at a lower temperature or a higher temperature than the center of the first area 110a and may be heated at the same temperature as the center of the first area 110a. Accordingly, deposition rates of the center and the edge of the substrate may be allowed to be uniform and occurrence of particles on the edge of the substrate may be prevented. That is, when the temperature of the edge of the substrate is higher than the temperature of the center of the substrate, the deposition rate of the edge of the substrate may be higher than the deposition rate of the center of the substrate. When the temperature of the edge of the substrate is lower than the temperature of the center of the substrate, particles may be generated on the edge of the substrate. The second area 110b is formed as a shape considering the first area 110a and the projecting portions 120. That is, an inside of the second area 110b may be formed along a shape of the first area 110a, for example, as a circle and an outside of the second area 110b may be formed between the edge of the substrate support 110 and the projecting portions 120 with uniform distances d1. That is, the second area 110b has the inside formed as a circle and the outside formed along the shape of the edge of the substrate support 110 and the projecting portions 120. Also, the second area 110b, as shown in FIGS. 3A to 3D, may be provided to have various cross sections. As shown in FIG. 3A, the second area 110b may be provided maintaining the same height lower than the first area 110a. As shown in FIG. 3B, the second area 110b may be provided maintaining the same height higher than the first area 110a. Also, as shown in FIG. 3C, the second area 110b may be formed to be lower than the first area 110a to allow a thickness to be reduced from a part in contact with the first area 110a to the outside. As shown in FIG. 3D, the second area 110b may be formed to be higher than the first area 110a and to be partially overlapped with the first area 110a. As shown in FIGS. 3A and 3C, when the height of the second area 110b is lower than the first area 110a, it is possible to contain a substrate having an area greater than the first area 110a. As shown in FIGS. 3B and 3D, when the height of the second area 110b is lower than the first area 110a, it is possible to contain a substrate having an area identical to or smaller than the first area 110a.

The projecting portions 120 are formed to project from certain parts of the edge of the substrate support 110 with a certain width and may be provided at least three. The projecting portions 120 may be formed to have the same shape and interval. For example, when the three projecting portions 120 are provided, the projecting portions 120 may be provided to form 120° from the center of the substrate support 110. Also, the projecting portions 120 may be provided to have the same thickness as the substrate support 110. However, the thickness of the projecting portions 120 may be thinner or thicker than the substrate support 110.

The supporting posts 130 may be provided on the bottom of the projecting portions 120 and may have the same shape and length. Herein, the supporting posts 130 may support a part of the substrate support 110. That is, the projecting portion 120 may be provided to be broader than a width of the supporting post 130 to allow the supporting post 130 to be connected to the projecting portion 120 on the bottom of the projecting portion 120.

The projecting portion 120 is formed to be narrower than the width of the supporting post 130 to allow the supporting post 130 to be provided on the bottom of the projecting portion 120 while including a part of the substrate support 110. In this case, the supporting post 130 may not project from an outside of the projecting portion 120. The supporting post 130 supports the substrate support 110 by supporting the projecting portion 120 on the bottom of the projecting portion 120. Also, the supporting post 120 may ascend or descend to allow the substrate support 110 to ascend or descend. Herein, to allow the substrate support 110 to ascend or descend while maintaining level, the at least three supporting posts 130 may ascend or descend at the same speed and height.

There has been described the substrate supporter including the substrate support 110 formed with the plurality of projecting portions 120 on the outside thereof and including the supporting posts 130 supporting the respective projecting portions 120 on the bottom of the projecting portions 120. However, the projecting portions 120 may not be additionally provided but the plurality of supporting posts 130 may support the substrate support 110 on the edge of the bottom of the substrate support 110. That is, there may be included various cases, in which the plurality of supporting posts 130 support the substrate support 110 on the outside of the substrate support 110 excluding the center thereof.

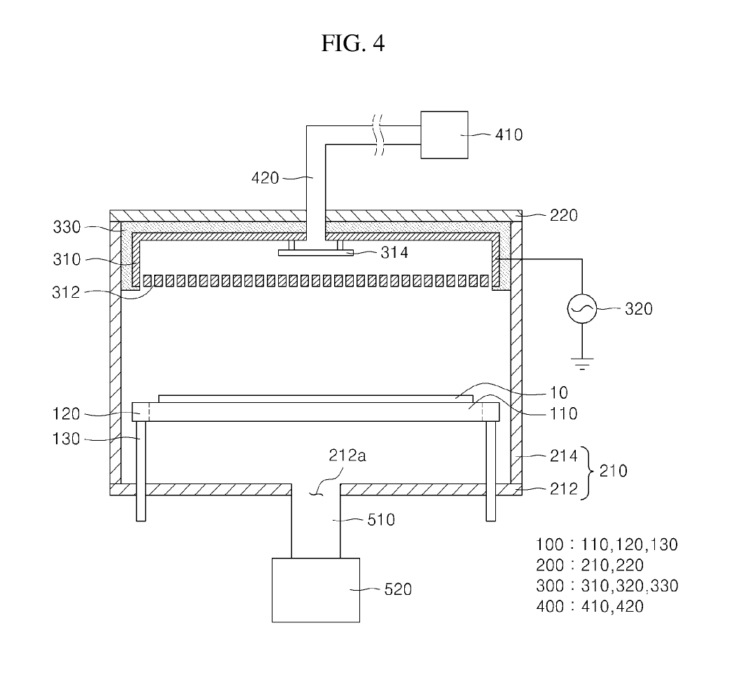

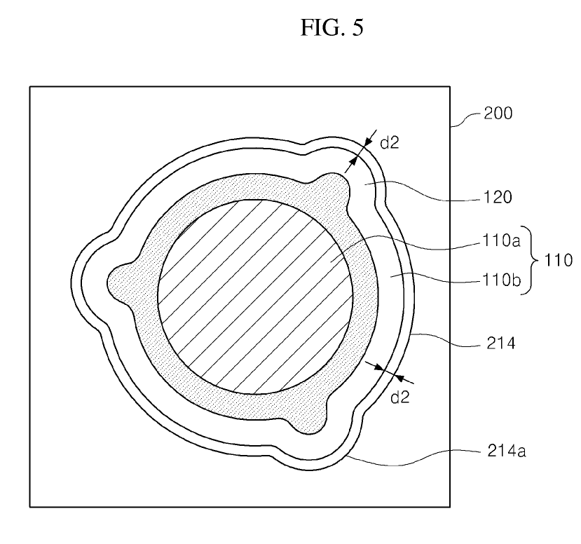

The substrate supporter may be used for a substrate processing apparatus using plasma, whose longitudinal cross-sectional view and lateral cross-sectional view are illustrated in FIGS. 4 and 5, respectively.

Referring to FIGS. 4 and 5, the substrate processing apparatus may include a chamber 200 provided with a certain reaction space, a substrate supporter 100 supporting a substrate 10, a gas injection assembly 300 provided in the chamber 200 and injecting a processing gas, a gas supplier 400 supplying the processing gas, and an exhauster 500 provided on a bottom of the chamber 200 to exhaust the chamber 200.

The substrate supporter 100 includes the substrate support 110 on which the substrate 10 is seated, the projecting portions 120 provided outside the substrate support 110, and the supporting posts 130 provided on the bottom of the projecting portions 120 and supporting the projecting portions 120. The substrate support 110 may support the substrate 10 to allow the substrate 10 to be seated and may be mounted with a heater (not shown) for heating the substrate 10. Also, a cooling tube (not shown) through which a refrigerant circulates may be further provided inside the substrate support 110 in addition to the heater, thereby controlling a temperature of the substrate 10 to be desirable. Also, the substrate support 110 may be divided into a plurality of areas according to a temperature. For example, the substrate support 110 may include the first area 110a for allowing the substrate 10 to be seated and increasing the temperature of the substrate to a processing temperature and a second area 110b provided outside the first area 110a and compensating a temperature of an edge of the substrate 10. The projecting portions 120 are formed to project from certain parts of the edge of the substrate support 110 with a certain width and may be provided at least three. The projecting portions 120 may be formed to have the same shape and interval. For example, when the three projecting portions 120 are provided, the projecting portions 120 may be provided to form 120° from the center of the substrate support 110. The supporting posts 130 may be provided on bottoms of the projecting portions 120 and may have the same shape and length. The supporting post 130 supports the substrate support 110 by supporting the projecting portion 120 on the bottom of the projecting portion 120. Also, the supporting post 120 may ascend or descend to allow the substrate support 110 to ascend or descend. Herein, to allow the substrate support 110 to ascend or descend while maintaining level, the at least three supporting posts 130 may ascend or descend at the same speed and height. On the other hand, when the projecting portions 120 and the supporting posts 130 are provided two, respectively, it may be difficult to maintain level of the substrate support 110 while supporting the substrate support 100 and ascending and descending. When the projecting portions 120 and the supporting posts 130 are provided five or more, respectively, parts occupied by the projecting portions 120 and the supporting posts 130 increase in such a way that an exhaust space is reduced, thereby increasing an exhaust time and making it difficult to control exhaust pressure. Accordingly, the projecting portions 120 and the supporting posts 130 may be provided three or four, respectively, to most stably maintain a balance of the substrate support 110 and not to allow the parts thereof to increase. On the other hand, although not shown in the drawings, a driving unit (not shown) for allowing the supporting post 130 to ascend and descend may be provided on a bottom of the supporting post 130. Also, the substrate supporter 100 is connected to a bias power source (not shown) and it is possible to control energy of ions injected into the substrate 10 by using bias power.

The chamber 200 may include a reaction part 210 having a certain space including a flat surface 212 having an approximately circular shape and a sidewall 214 extended upwards from the flat surface 212 and a cover 220 having an approximately circular shape and located above the reaction part to airtightly maintain the chamber 200. The sidewall 214 may maintain a certain interval from the substrate supporter 100, in which a side surface of the substrate supporter 100 and the sidewall 214 may maintain the same interval throughout the entire area. When the substrate supporter 100 and the sidewall 214 maintain the same interval throughout the entire area, exhaustion may be performed with the same pressure from an upper area of the substrate supporter 100 through the side surface. Accordingly, it is possible to allow exhaustion speed and pressure to be uniform, thereby improving uniformity of a thin film on the substrate 10 and restraining occurrence of particles. However, the substrate supporter 100 is provided with at least three projecting portions 120 supported by at least three supporting posts 130, respectively, outside the substrate support 110 on which the substrate is seated and supported. As described above, to allow the projecting portions 120 to project from the substrate support 110 and to allow a side surface of the substrate support 110 and side surfaces of the projecting portions 120 to maintain the same distance d2 from the sidewall 214 of the chamber 200, the sidewall 214 is formed with a groove 214a to contain the projecting portions 120. That is, the sidewall 214 is formed with the groove 214a having certain width and depth on a side surface thereof. Accordingly, in the substrate supporter 100, the substrate supporter 110 is separate from the sidewall 214 with a certain interval and the projecting portions 120 are allowed to ascend and descend inside the chamber 200 while being separate from the groove 214a with a certain interval. Also, a bottom of the chamber 200, that is, a central portion of the flat surface 212 is formed with an exhaustion opening 212a connected to the exhauster 500 including an exhaustion tube, an exhaustion unit, etc. Also, separate from the central portion, a penetration hole, through which the supporting post 130 of the substrate supporter 100 passes, may be formed.

The gas injection assembly 300 supplies the processing gas into the chamber 200 and excites the processing gas to be plasma. The gas injection assembly 300 includes a gas injection unit 310 injecting the processing gas such as a deposition gas, an etching gas, etc. into the chamber 200 and a power supplying unit 320 applying high frequency power to the gas injection unit 310. The gas injection unit 310 is provided as a shower head type, installed on a top in the chamber 200 to be opposite to the substrate supporter 100, and injects the processing gas toward the bottom of the chamber 200. The gas injection unit 310 is provided with a certain space therein. A top of the gas injection unit 310 is connected to the processing gas supplier 400, and a bottom is formed with a plurality of injection holes 312 for injecting the processing gas onto the substrate 10. The gas injection unit 310 is manufactured as a shape corresponding to the substrate 10 and may be manufactured as an approximately circular shape. Also, inside the gas injection unit 310, a distribution plate 314 for evenly distributing the processing gas supplied from the gas supplier 400. The distribution plate 314 may be connected to the processing gas supplier 400, may be provided adjacently to a gas inlet, into which the processing gas flows, and may be formed to have a certain plate shape. That is, the distribution plate 314 may be provided while being separate from a top surface of the shower head 310 with a certain interval. Also, the distribution plate 314 may be formed with a plurality of penetration holes thereon. As described above, the distribution plate 314 is provided, thereby allowing the processing gas supplied from the processing gas supplier 400 to be evenly distributed inside the gas injection unit 310. According thereto, the processing gas may be evenly injected through the injection hole 312 of the gas injection unit 310 toward the bottom. Also, the gas injection unit 310 may be manufactured using a conductive material such as aluminum and may be provided while being separate from the sidewall 214 and the cover 220 of the chamber 200 with a certain interval. Between the gas injection unit 310 and the sidewall 214 and the cover 220 of the chamber 200, an insulator 330 is provided to insulate the gas injection unit 310 and the chamber 200 from each other. Since the gas injection unit 310 is manufactured using the conductive material, the gas injection unit 310 may be used as an upper electrode for receiving high frequency power from the power supplying unit 320 and generating plasma. The power supplying unit 320 penetrates the sidewall 214 of the chamber 200 and the insulator 340, is connected to the gas injection unit 310, and supplies the high frequency power for generating plasma to the gas injection unit 310. The power supplying unit 320 may include a high frequency power source (not shown) and a matching unit (not shown). The high frequency power, for example, generates high frequency power of about 13.56 MHz, the matching unit detects impedance of the chamber 200 and generates imaginary number elements of the impedance and imaginary number elements of impedance of an inverted phase, thereby supplying maximum power to the chamber to allow the impedance to be identical to a pure resistance, which is a real number, and then generating optimum plasma. On the other hand, since the gas injection assembly 300 is provided above the chamber 200 and the high frequency power is applied to the shower head 310, the chamber 200 is grounded, thereby generating plasma of the processing gas inside the chamber 200.

The gas supplier 400 includes a gas supply source 410 supplying a plurality of processing gases, respectively, and a gas supply pipe 420 supplying the processing gas from the gas supply source 410 to the shower head 310. The processing gas, for example, may include an etching gas and a thin film deposition gas. The etching gas may include NH₃, NF₃, etc. The thin film deposition gas may include SiH₄, PH₃, etc. Also, in addition to the etching gas and thin film deposition gas, inert gases such as H₂, Ar, etc. may be supplied. Also, between the processing gas supply source and the processing gas supply pipe, a valve controlling supplying of the processing gas and a mass flow unit may be provided.

The exhauster 500 may include an exhaustion pipe 510 connected to the exhaustion opening 212a formed in the central portion of flat surface 212 and an exhaustion unit 520 exhausting the inside of the chamber 200 through the exhaustion pipe 510. In this case, the exhaustion pipe 520 may be a vacuum pump such as a turbo molecular pump configured to vacuum suck the inside of the chamber 200 is vacuum to form a certain decompressive atmosphere, for example, to a certain pressure of about 0.1 mTorr or less. The exhauster 500 is provided in the center of the bottom of the chamber 200, thereby exhausting the inside of the chamber 200 with uniform pressure.

On the other hand, it has been described that the substrate processing apparatus includes the gas injection assembly 300 applying the high frequency power to the gas injection unit 310 in the chamber 200 as an example. However, the substrate processing apparatus is not limited thereto and may include a plasma generator generating plasma using various methods. For example, an electrode may be formed above the gas injection unit 310 while being separate from the gas injection unit 310 and high frequency power may be applied to the electrode, thereby generating plasma. Otherwise, an antenna may be provided on a top or a side of the outside of the chamber 200 and high frequency power may be applied to the antenna, thereby generating plasma.

As described above, the substrate supporter is formed with the plurality of projecting portions 120 outside the substrate support 110 supporting the substrate and is provided with the supporting posts 130 on the bottoms of the projecting portions 120 to support the edge of the substrate support 110. Also, in the substrate processing apparatus, the exhaustion opening 212a is formed in the center of the bottom of the chamber 200 and is connected to the exhauster 500 and the supporting posts 130 separate from the exhaustion opening 212a not to be overlapped with the exhaustion opening 212a and supporting the substrate support 110 through the projecting portions 120 on the edge of the substrate support 110 are provided. That is, the substrate processing apparatus exhausts the inside of the chamber 200 in the center of the bottom of the chamber 200 and supports the substrate support 110 on the edge of the bottom of the chamber 200. Accordingly, a gas flow is allowed to be uniform throughout the entire area inside the chamber 200, thereby improving uniformity of thin film deposition on the substrate 10 and restraining occurrence of particles. That is, since the gas flow is uniform inside the chamber 200, a detention time of a processing gas throughout the entire area on the substrate 10 is allowed to be uniform, thereby improving the uniformity of thin film deposition and restraining the occurrence of particles because the detection time of the processing gas in one area does not increase.

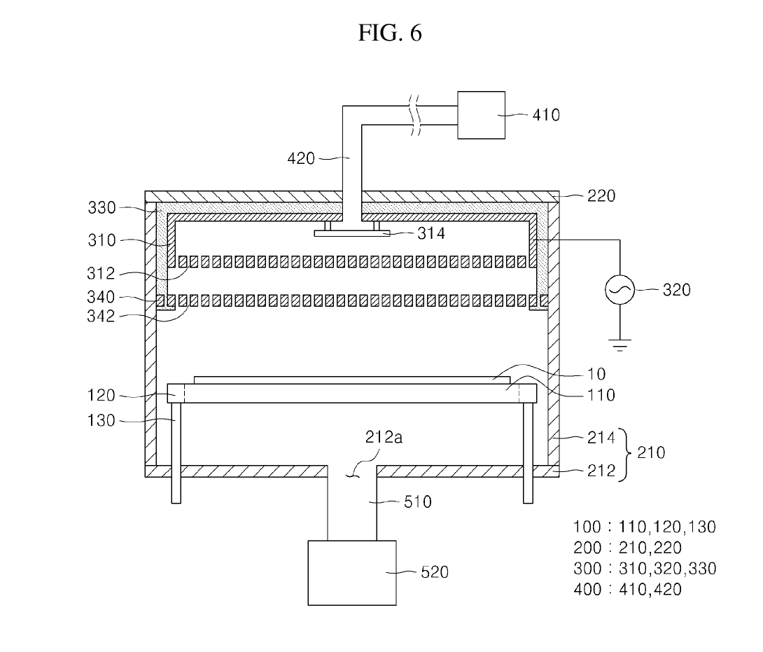

FIG. 6 is a cross-sectional view of a substrate processing apparatus according to another embodiment, in which the gas injection assembly 300 includes a ground plate 340. The ground plate 340 may be provided while being separate from the gas injection unit 310 with a certain interval and may be connected to the side surface of the chamber 200. The chamber 200 is connected to a ground terminal, and then the ground plate 340 maintains a ground potential. On the other hand, a space between the gas injection unit 310 and the ground plate 340 becomes a reaction space for exciting the processing gas injected through the shower head 310 to be plasma. That is, when the processing gas is injected through the gas injection unit 310 and high frequency power is applied to the gas injection unit 310, since the ground plate 340 maintains a ground state, a potential difference occurs therein, thereby exciting the processing gas to be plasma in the reaction space. Herein, the space between the gas injection unit 310 and the ground plate 340, that is, a distance between top and bottom of the reaction space may maintain at least distance for allowing the plasma to be excited. For example, the distance of about 3 mm or more may be maintained. As described above, it is necessary to inject the processing gas excited in the reaction space onto the substrate 10. For this, the ground plate 340 is provided as a certain plate shape formed with a plurality of holes 342 penetrating top and bottom thereof. The ground plate 340 is provided as described above, it is prevented that the plasma generated in the reaction space is in direct contact with the substrate 10, thereby reducing plasma damages of the substrate 10. Also, the ground plate 340 keeps the plasma in the reaction space to decrease an electron temperature.

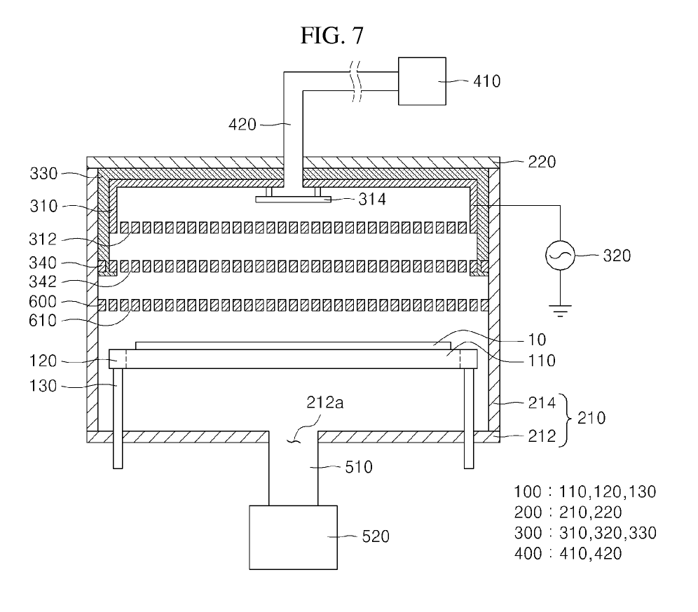

FIG. 7 is a cross-sectional view of a substrate processing apparatus according to still another embodiment, including a filter 600 provided between the substrate supporter 100 and the gas injection assembly 300. The filter 600 is provided between the ground plate 340 and the substrate supporter 100, and a side surface thereof is connected to the sidewall of the chamber 200. Accordingly, the filter 600 maintains a ground potential. The filter 600 filters out ions, electrons, and light of plasma generated by the gas injection assembly 300. That is, when the plasma generated by the gas injection assembly 300 passes through the filter 600, ions, electrons, and light are shut off to allow only reactive species to react with the substrate 10. The filter 600 allows the plasma to be applied to the substrate 10 after colliding with the filter 600 at least once. Through this, when the plasma collides with the filter 600 of the ground potential, ions and electrons having energy may be absorbed. Also, the light of the plasma collides with the filter 600 and is not allowed to penetrate. The filter 600 may be formed as various shapes, for example, may be formed as a single plate formed with a plurality of holes 610, may be formed as multiple plates by multiply disposing plates formed with the holes 610 to allow the holes 610 of the respective plates to be diagonal from one another, or may be formed as a plate formed with the plurality of holes 610 having certain refractive paths.

Also, in the embodiments, a gas injection assembly may be variously modified. A substrate processing apparatus according to even another embodiment will be described as follows.

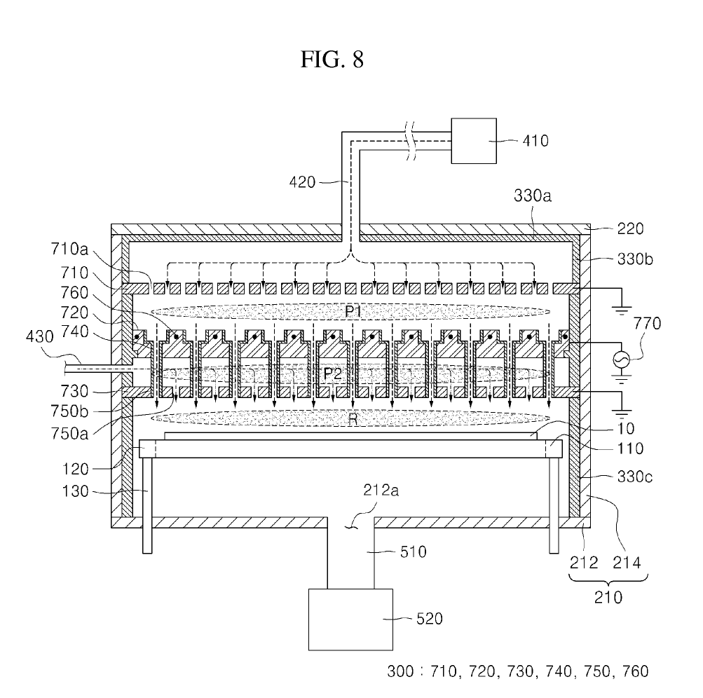

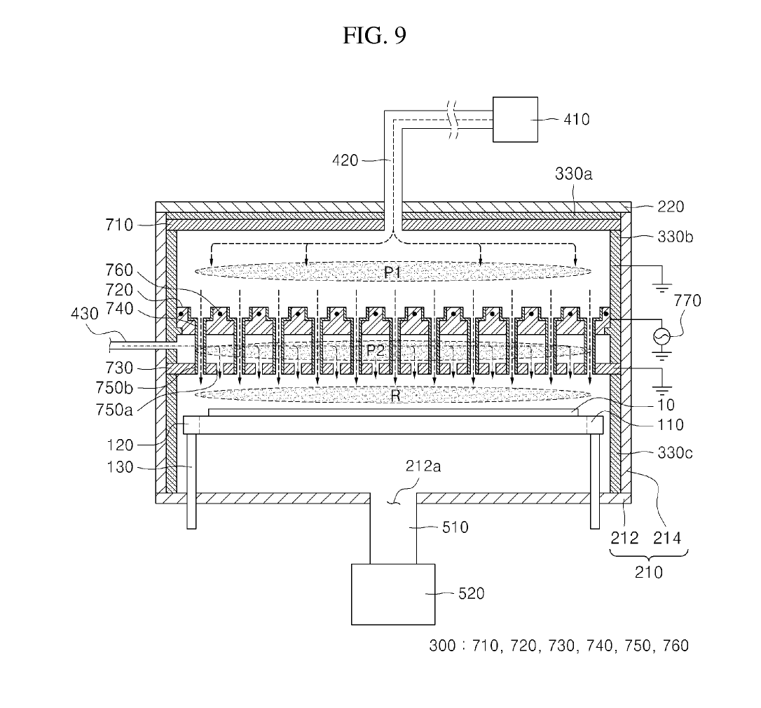

As shown in FIG. 8, the substrate processing apparatus may include a gas injection assembly 700 including an upper body 710 disposed above the substrate supporter 100 in the chamber 200, a gas injection unit including first and second bodies 720 and 730 disposed while being separate from each other top and bottom below the upper body 710, and a power supplying unit 770 applying power to the second body 730. The gas injection assembly 700 and the gas supplier 400 may include a first gas supply pipe 420 supplying a processing gas toward a bottom of the upper body 710 and a second gas supply pipe 430 supplying the processing gas to a space between the first body 720 and the second body 730.

The upper body 710 is disposed below a first insulating member 330a provided on an upper wall inside the chamber 200 while being separate therefrom. The upper body 710 is manufactured as a plate shape and includes a plurality of holes 710a connected top and bottom. A top of the upper body 710 is connected to the first gas supply pipe 420 supplying the processing gas. The processing gas supplied through the first gas supply pipe 420 is dispersed in a space between the first insulating member 330a and the upper body 710 and then is injected downwards through a plurality of holes 710a provided on the upper body 710. At least one end of the upper body 710 is in contact with an inner wall of the grounded chamber 200 or is connected to be grounded separately from the chamber 200. On the other hand, on the sidewall of the chamber 200 inside the upper body 710, the second insulating member 330b is provided.

The gas injection unit includes the first body 720 disposed below the upper body 710 to be separate therefrom, the second body 730 disposed below the first body 720 and including a plurality of first injection holes 730a and a plurality of second injection holes 730b injecting the processing gas, a plurality of connecting pipes 740 inserted and installed to penetrate the first body 720 and the second body 730 and injecting the processing gas, and a cooling member 760 installed inside the first body 720 and cooling down the first body 720. Herein, parts not installed with the plurality of connecting pipes 740 between the first body 720 and the second body 730 is empty spaces. The empty spaces between the first body 720 and the second body 730 are connected to a plurality of first injection holes 750a provided on the second body 730. Also, the second gas supply pipe 430 is installed to allow at least one end to be inserted into the chamber 200 while penetrating the sidewall of the chamber 200 and supplies the processing gas to a space between the first body 720 and the second body 730. However, the second gas supply pipe 430 is not limited thereto may be installed to extend downwards from the top to the bottom of the chamber 200 to allow one end to be installed in a separate space between the first body 720 and the second body 730.

The first body 720 is disposed below the upper body 710 to be separate therefrom and is connected to the power supplying unit 770 applying power for generating plasma. For this, at least one end of the power supplying unit 770 penetrates the second insulating member 330b installed on the inner wall of the chamber 200 and is connected to the first body 720. Also, when the power is supplied into the first body 720, since unnecessary heat may occur in the first body 720, the cooling member 760 is inserted and installed in the first body 720. The cooling member 760 may be a pipe, through which a refrigerant, for example, water or a nitrogen gas flows.

The second body 730 is disposed below the first body 720 to be separate therefrom, and at least one end thereof is in contact with the inner wall of the chamber 200 or is connected to be separately grounded. The second body 730 is provided with the plurality of first injection holes 750a and a plurality of second injection holes 750b, whose top and bottom are open, disposed above the second body 730 to be separate from one another. That is, the plurality of first injection holes 750a are located or the first injection hole 750a is located between the plurality of second injection holes 750b. That is, on the second body 730, the first injection holes 750a and the second injection holes 750b are alternately disposed. Herein, the plurality of first injection holes 750a is transfer flow channels, through which the plasma generated between the first body 720 and the second body 730 passes and is injected downwards from the second body 730. Also, the plurality of second injection hole 750b is a space, into which the connecting pipes 740 to be described below are inserted, respectively.

The connecting pipes 740 are manufactured to have open top and bottom and to be a pipe shape having an inner space and are inserted and installed to penetrate the first body 720 and the second body 730 from top to bottom. That is, the connecting pipes 740 are installed to penetrate the first body 720 and to allow one ends thereof to be inserted into the second injection holes 750b provided in the second body 730. Herein, the connecting pipes 740 on the second body 730 are located between the plurality of second injection holes 750b. The connecting pipes 740 are flow channels allowing the plasma generated between the upper body 710 and the first body 720 to pass therethrough and to move downwards from the second body 730. Also, the connecting pipes 740 are manufactured to allow diameters of areas thereof inserted into the bottom of the first body 720 and the second injection hole 750b of the second body 730 to be smaller than a diameter of an area located in the first body 720. Particularly, the diameters of the areas inserted into the bottom of the first body 720 and inserted into the second injection hole 750b in the second body 730 may be identical to one another and may be smaller than the diameter of the area located in the first body 720. For example, the connecting pipe 740 is manufactured to allow a cross section thereof to have a T shape. However, the connecting pipe 740 is not limited thereto and may be manufactured as various shapes connecting the first body 720 to the second body 730 and having an inner space, through which the processing gas flows. Also, to insulate the first body 720 from the second body 730, the connecting pipe 740 may be manufactured using an insulating material, for example, a plate formed of ceramic or Pyrex or applying a material formed of ceramic or Pyrex to form a coating film. Also, an inner diameter of the connecting pipe 740 and a size of the first injection hole 750a provided in the second body 730 may be 0.01 inch or more. This is for restraining occurrence of arcing while applying power to the gas injection unit and for restraining parasitic plasma while generating plasma.

As follows, a process of generating plasma in the space between the upper body 710 and the first body 720 and the space between the first body 720 and the second body 730 will be described.

When the processing gas is supplied from the first gas supply pipe 420 to a top of the upper body 710, the processing gas is injected downwards from the upper body 710 through the plurality of holes 710a. Herein, when radio frequency (RF) power is supplied to the first body 720 by using the power supplying unit 770 and the upper body 710 is grounded, the processing gas is discharged in a separate space between the upper body 710 and the first body 720, thereby generating first plasma. In the following, the separate space between the upper body 710 and the first body 720 is designated as a first plasma area P1 and plasma generated in the first plasma area P1 is designated as the first plasma. Since the first plasma area P1 is a space defined when a top, that is, the upper body 710 is grounded and the RF power is applied to a bottom, that is, the first body 720, the first plasma having high density and high ion energy is generated in the first plasma area P1. Herein, the first plasma may be reactive ion deposition (RID) plasma generated when the top is grounded and the RF power is applied to the bottom. The first plasma has high density and high ion energy incident on a substrate S and has a broad sheath area. The first plasma generated in the first plasma area P1 is transferred downwards from the gas injection unit through the connecting pipes 740. In the following, a space below the gas injecting unit, that is, an area between the second body 730 and the substrate supporter 100 is designated as a reactive area R. Herein, the first plasma has properties of high density and high ion energy.

Also, when the processing gas is supplied from the second gas supply pipe 430 to the space between the first body 720 and the second body 730, the processing gas is dispersed in the space between the first body 720 and the second body 730. Herein, when the RF power is supplied to the first body 720 by using the power supplying unit 770 and the second body 730 is grounded, second plasma is generated in a separate space between the first body 720 and the second body 730. Herein, since the second plasma is plasma enhanced CVD (PECVD) generated when the RF power is applied to the top and the bottom is grounded and has a low plasma density and a broad sheath area, a processing speed is high. In the following, the separate space between the upper body 710 and the first body 720 is designated as a second plasma area P2 and plasma generated in the second plasma area P2 is designated as the second plasma. Herein, since the second plasma area P2 is a space defined when the bottom, that is, the second body 730 is grounded and the RF power is applied to the top, that is, the first body 720, the second plasma having lower density and ion energy than the first plasma is generated in the second plasma area P2. After that, the second plasma generated in the second plasma area P2 is transferred to the reactive area R through the plurality of first injection holes 750a provided in the second body 730.

As described above, the processing gas is injected through the upper body 710 and the gas injection unit, respectively, thereby partitively injecting the processing gas. Also, since applying power to the upper body 710 and applying power to the gas injection unit are independently controlled, respective occurrences of plasma in the first plasma area P1 between the upper body 710 and the gas injection unit and the second plasma area P2 inside the gas injection unit may be independently controlled. Accordingly, it is possible to provide film properties having excellent step coverage.

Herein, since bias power is applied to the substrate supporter 100 seated with the substrate 10 on the top thereof, ions of the first and second plasmas transferred to the reactive area R are incident on or collide with the surface of the substrate 10, thereby etching a thin film formed on the substrate 10 or depositing a thin film on the substrate 10. As described above, the first plasma generated in the first plasma area P1 has high density and ion energy and the second plasma generated in the second plasma area P2 has lower density and ion energy than the first plasma. When the first plasma is separately used, the substrate 10 or the thin film formed on the substrate 10 may be damaged. When the second plasma is separately used, the processing speed is low. However, in the embodiments, the first plasma having high density and ion energy and the second plasma having lower density and ion energy than the first plasma are generated together, thereby improving the processing speed while preventing damages of the substrate 10 or the thin film due to interaction between the first plasma and the second plasma.

In the above, as shown in FIG. 8, it has been described that the upper body 710 is disposed below the insulating member 330a to be separate therefrom and is provided with the plurality of holes 710a. However, it is not limited thereto, and as shown in FIG. 9, the upper body 710 may be installed to be in contact with a bottom of the first insulating member 330a and the plurality of holes 710a may not be provided. Herein, the first gas supply pipe 420 injects the processing gas downwards from the upper body 710.

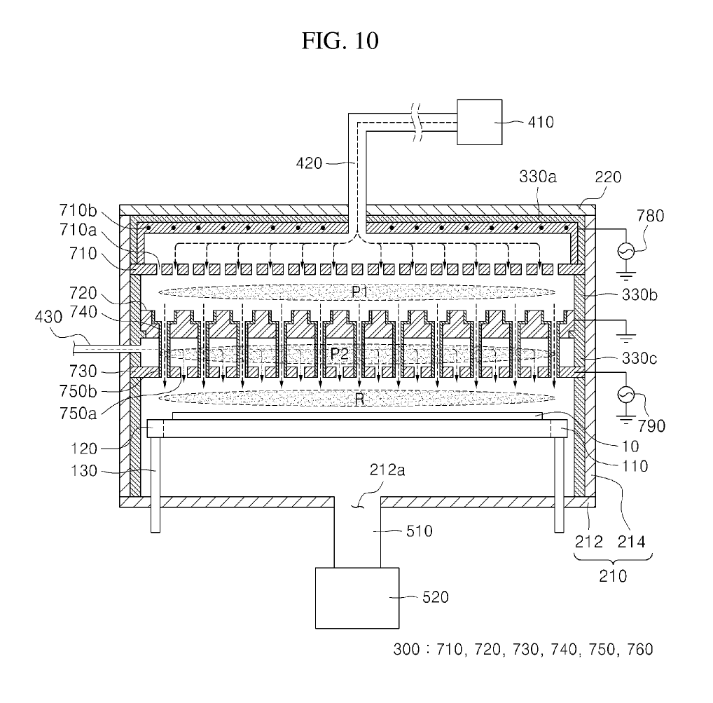

Also, in the above, as shown in FIGS. 8 and 9, it has been described that the first body 720 of the gas injection unit and the power supplying unit 770 are connected to each other, thereby supplying the RF power to the first body 720 and allowing the upper body 710 and the second body 730 to be grounded. However, it is not limited thereto, and as shown in FIG. 10, the first body 720 of the gas injection unit may be grounded, the upper body 710 located above the first body 720 may be connected to a power supplying unit 780 applying, for example, RF power, and the second body 730 located below the first body 720 may be connected to a power supplying unit 790. Since the first plasma area P1 has a structure, in which power is supplied to a top, that is, the upper body 710 and a bottom, that is, the first body 720 is grounded, the first plasma generated in the plasma area P1 has lower density and ion energy than the second plasma. Also, the second plasma area P2 has a structure, in which the top, that is, the upper body 710 is grounded and power is supplied to the bottom, that is, the second body 730, the second plasma generated in the second plasma area P2 has higher density and ion energy than the first plasma generated in the first plasma area P1. Also, in a case as described above, as shown in FIG. 10, a cooling member 710b cooling down the upper body 710 is inserted into and installed in the upper body 710.

In the following, referring to FIG. 8, operations of the substrate processing apparatus and a method of processing a substrate will be described.

The substrate 10 is inserted into the chamber 200 and is seated on the substrate supporter 100 disposed in the chamber 200. In the embodiment, the substrate 10 is a wafer but is not limited thereto and may be a glass substrate, a polymer substrate, a plastic substrate, a metal substrate, etc.

When the substrate 10 is seated on the substrate supporter 100, a processing gas is supplied to a top of the upper body 710 through the first gas supply pipe 420 and a processing gas is supplied to a space between the first body 720 and the second body 730 of the gas injection unit through the second gas supply pipe 430. In the embodiment, as the processing gas, an etching gas for etching a thin film on the substrate 10 is used. In the embodiment, the processing gas is one of SiHr, TEOS, O₂, Ar, He, NH₃, N₂O, N2, and CaHb but is not limited thereto and may be various materials.

Also, RF power is supplied to the first body 720 by using the power supplying unit 770, and the upper body 710 and the second body 730 are grounded, respectively. The processing gas supplied from the first gas supply pipe 420 is injected downwards from the upper body 710, that is, into the first plasma area P1 through the plurality of holes 710a provided in the upper body 710. After that, the first plasma having high density and ion energy is generated in the first plasma area p1 by the grounded upper body 710 and the first body 720 applied with the RF power. The first plasma generated in the first plasma area P1 is transferred to the reactive area R through the connecting pipes 740. Herein, as described above, the connecting pipes 740 are installed to extend from the inside of the first body 720 to the inside of the second body 730 disposed below the first body 720 to allow the first plasma generated in the first plasma area P1 to be uniformly injected into the reactive area R through the connecting pipes 740, thereby allowing the density of the first plasma in the reactive area R to be uniform.

Also, the processing gas provided from the second gas supply pipe 430 is uniformly dispersed in the space between the first body 720 and the second body 730, that is, throughout the entire second plasma area P2. After that, the second plasma is generated in the second plasma area P2 by the first body 720 applied with the RF power and the grounded second body 730. The second plasma generated in the second plasma area P2 is transferred to the reactive area R through the plurality of first injection holes 750a and is evenly dispersed throughout the entire reaction area R through the plurality of first injection holes 750a.

The first and second plasmas transferred to the reactive area R change in properties such as density, ion energy, etc. due to interaction. That is, the first plasma transferred to the reactive area R is reduced in density and ion energy than in the first plasma area P1, which is caused by offset by the second plasma met in the reactive area R. Also, the second plasma transferred to the reactive area R is increased in density and ion energy than in the second plasma area P2, which is caused by offset by the first plasma met in the reactive area R.

After that, ions of the first and second plasmas in the reactive area R are incident on or collide with the substrate 10 applied with bias power, thereby etching the thin film formed on the substrate 10. Herein, although not shown in the drawing, a mask (not shown) provided with a plurality of openings may be disposed above the substrate 10 and the ions of the first and second plasmas are incident on the substrate 10 through the openings of the mask and etch the thin film formed on the substrate 10. Herein, in the embodiment, differently, instead of independently using plasma having high density and ion energy or plasma having low density and ion energy, the plasma having high density and ion energy and the plasma having lower density and ion energy than the same are used together, thereby preventing damages of the thin film or the substrate 10 caused by ions heading for the substrate 10 and reducing a processing time.

In the above, the substrate processing apparatus of FIG. 8 has been described as an example. However, operations of the substrate processing apparatuses of FIGS. 9 and 10 and processes of generating plasma are similar. Merely, in FIG. 9, the processing gas supplied to the first gas supply pipe 420 is directly injected downwards from the upper body 710. Also, in FIG. 10, the upper body 710 and the second body 730 are grounded and the first body 720 is connected to the power supplying unit 790. The first plasma is generated between the upper body 710 and the first body 720 and the second plasma is generated between the first body 720 and the second body 730. Herein, the second plasma has higher density and ion energy than the first plasma.

Herein, the second plasma generated between the first body 720 and the second body 730 has higher density and ion energy than the first plasma generated between the upper body 710 and the first body 720.

A substrate supporter according to the embodiments is provided with a plurality of supporting posts to support an outside of the substrate support supporting a substrate. Also, a substrate processing apparatus is provided with an exhauster including an exhausting unit in a center of a bottom of a chamber and is provided with the substrate supporter outside the exhauster. Accordingly, since the exhauster is provided in the center of the chamber, a gas flow inside the chamber may be more uniformly than a general case, in which an exhauster is provided on a side of a chamber, thereby improving uniformity of depositing a thin film on the substrate and restraining occurrence of particles.

Also, a substrate processing apparatus according to other embodiments, first plasma is generated in a first plasma area corresponding to an inside or an outside of an electrode member and second plasma is generated in a second plasma area inside a gas injection unit. Herein, one of the first and second plasmas has high ion energy and density and another has lower ion energy and density than the same. As described above, the first and second plasmas having different ion energies and densities are used together, a substrate processing speed may be improved and damages of the substrate or the thin film may be reduced.

Also, the substrate processing apparatus includes a gas injection unit installed to extend from a first body to a second body and a plurality of connecting pipes disposed to be separate from one another. The first plasma generated in the first plasma area is uniformly dispersed in a reactive area located below a shower head through the connecting pipes. Accordingly, a uniform processing condition may be maintained throughout the entire substrate.

Although the substrate supporter and the substrate processing apparatus have been described with reference to the specific embodiments, they are not limited thereto. Therefore, it will be readily understood by those skilled in the art that various modifications and changes can be made thereto without departing from the spirit and scope of the present invention defined by the appended claims.

What is claimed is:

1. A substrate supporter comprising:
a substrate support supporting a substrate; and
a plurality of supporting posts supporting an edge of the substrate support below the substrate support.

2. The substrate supporter of claim 1, further comprising a plurality of projecting portions projecting outwards from the edge of the substrate support,
wherein the plurality of supporting posts support bottoms of the projecting portions, respectively.

3. The substrate supporter claim 1, wherein the substrate support comprises:
a first area in contact with a rear of the substrate and heating the substrate while maintaining a first temperature; and
a second area provided outside the first area and maintaining a second temperature higher or lower than the first temperature.

4. The substrate supporter of claim 3, wherein the second area is provided higher or lower than the first area.

5. A substrate processing apparatus comprising:
a chamber provided with a reaction space and formed with an exhaustion opening in a center of a bottom;
a substrate supporter provided in the chamber and supporting a substrate;
a gas injection assembly provided to be opposite to the substrate supporter, injecting a processing gas, and generating plasma thereof; and
an exhauster connected to the exhaustion opening and provided below the chamber to exhaust an inside of the chamber,
wherein the substrate supporter comprises a substrate support supporting the substrate and a plurality of supporting posts supporting an outside of the substrate support disposing the exhausting opening therebetween.

6. The substrate processing apparatus of claim 5, further comprising a plurality of projecting portions projecting outwards from an edge of the substrate support,
wherein the plurality of supporting posts support the projecting portions, respectively.

7. The substrate processing apparatus of claim 6, wherein the substrate support comprises:
a first area in contact with a rear of the substrate and heating the substrate while maintaining a first temperature; and
a second area provided outside the first area and maintaining a second temperature higher or lower than the first temperature.

8. The substrate processing apparatus of claim 5, wherein the gas injection assembly comprises:
a gas injection unit injecting the processing gas;
a power unit for applying high frequency power to the gas injection unit; and
a ground plate provided to be separate from the gas injection unit with a certain interval and formed with a plurality of penetration holes.

9. The substrate processing apparatus of claim 8, further comprising a filter provided between the gas injection unit and the substrate supporter and formed with a plurality of holes to shut out a part of plasma of the processing gas.

10. The substrate processing apparatus of claim 5, wherein the gas injection assembly comprises:
a gas injection unit injecting the processing gas;
an electrode separate from the gas injection unit; and
a power unit for applying high frequency power to the electrode.

11. The substrate processing apparatus of claim 10, further comprising a filter provided between the gas injection unit and the substrate supporter and formed with a plurality of holes to shut out a part of plasma of the processing gas.

12. The substrate processing apparatus of claim 5, wherein the gas injection assembly comprises:
a gas injection unit injecting the processing gas;
an antenna provided on one of a top and a side of an outside of the chamber; and
a power unit applying high frequency power to the antenna.

13. The substrate processing apparatus of claim 5, wherein the gas injection assembly comprises:
an upper body;
a first body disposed below the upper body to be separate therefrom;
a second body disposed below the first body and provided with a plurality of first injection holes and a plurality of second injection holes;
a connecting pipe comprising an inner space and installed to penetrate the first body and the second body top and bottom;
a power supplying unit applying power to at least one of the upper body, the first body, and the second body to form a plasma area between the upper body and the first body and a plasma area between the first body and the second body.

14. The substrate processing apparatus of claim 13, further comprising a first gas supply pipe supplying the processing gas to the upper body and a second gas supply pipe supplying the processing gas to an area between the first body and the second body.

15. The substrate processing apparatus of claim 13, wherein the first body is connected to the power supplying unit and the upper body and the second body are grounded.

16. The substrate processing apparatus of claim 13, wherein the upper body is connected to a first power supplying unit, a second body is connected to a second power supplying unit, and the first body is grounded.

17. The substrate processing apparatus of claim 13, wherein the upper body is formed with a plurality of holes connected top and bottom.

18. The substrate processing apparatus of claim 13, wherein the first injection holes and the second injection holes are alternately disposed to be separate from one another.

19. The substrate processing apparatus of claim 13, wherein the connecting pipe is manufactured using an insulating material.

20. The substrate processing apparatus of claim 13, wherein the connecting pipe penetrates the first body and is inserted into and installed in the second injection holes of the second body.

21. The substrate processing apparatus of claim 20, wherein among areas of the connecting pipe, an area connected to the first body has a diameter greater than a diameter of an area connected to the second body.
